(19) United States
(12) Patent Application Publication
(10) Pub. No.: US 2014/0290847 A1
(43) Pub. Date: Oct. 2, 2014

(54) OPTICAL SYSTEM AND SUBSTRATE SEALING METHOD

(71) Applicants: LTS Co., Ltd., Uiwang-Si (KR); Samsung Display Co., Ltd., Yonain-City (KR)

(72) Inventors: Jung-Min Lee, Yongin-City (KR); Young-Kwan Kim, Uiwang-Si (KR)

(73) Assignees: LTS Co., Ltd., Uiwang-Si (KR); Samsung Display Co., Ltd., Yonain-City (KR)

(21) Appl. No.: 13/953,661

(22) Filed: Jul. 29, 2013

(30) Foreign Application Priority Data
Mar. 29, 2013 (KR) 10-2013-0034697

(51) Int. Cl. H01L 33/00; G02B 27/09

(52) U.S. Cl. CPC H01L 33/005; G02B 27/0944; G02B 27/0905; H01L 2933/0008
USPC 156/272.2; 359/558

(57) ABSTRACT

An optical system includes an optical path, a first lens unit that changes light emitted from an end of the optical path to parallel light, a second lens unit that allows the parallel light to be focused, and a diffractive optical element (DOE) that changes light passing through the second lens unit to light having a cross-section with a predetermined shape.

### CROSS-REFERENCE TO RELATED APPLICATION

This application claims priority to and the benefit of Korean Patent Application No. 10-2013-0034697, filed on Mar. 29, 2013, in the Korean Intellectual Property Office, the disclosure of which is incorporated herein in its entirety by reference.

### BACKGROUND

1. Field

The present invention relates to an optical system and a substrate sealing method using the same.

2. Description of the Related Art

Display devices are being replaced with thin and portable flat panel display devices. Electroluminescence display devices among flat panel display devices are self-emitting display devices, having wide viewing angles, excellent contrast and short response speed, and thus have drawn attention as the next-generation display devices. Also, organic light-emitting display devices in which a light-emitting layer is formed of an organic material, have superior characteristics, such as high brightness, low driving voltages, and short response speed compared to inorganic light-emitting display devices, and can be multi-colored.

An organic light-emitting display device according to the related art has a structure in which at least one organic layer including a light-emitting layer is interposed between a pair of electrodes.

In such an organic light-emitting display device, when moisture or oxygen permeates into an organic light-emitting diode (OLED) from an ambient environment, the life span of the OLED may be reduced due to oxidation and exfoliation of electrode material, reduced emission efficiency, and changed emission color.

Thus, when the organic light-emitting display device is manufactured, sealing is generally performed so as to prevent moisture from permeating into the OLED by isolating the OLED from the outside. A method of laminating an inorganic thin film or organic polymer such as polyester (PE) on a second electrode of the organic light-emitting display device, or a method of sealing an edge/corner of an encapsulation substrate using a sealant such as epoxy after forming a moisture absorbent in the encapsulation substrate and filling the encapsulation substrate with a nitrogen gas, has been used for sealing.

Even with these methods, it is difficult to completely block destructive factors of the OLED, such as moisture and oxygen permeated from the outside. Thus, it is undesirable to apply the methods to the organic light-emitting display device that is vulnerable to moisture.

### SUMMARY

The embodiments of the present invention provide an optical system that may create a beam profile having a desired shape and a substrate sealing method using the same.

According to an aspect of an embodiment of the present invention, an optical system is provided including an optical path, a first lens unit configured to change light emitted from an end of the optical path to parallel light, a second lens unit configured to focus the parallel light, and a diffractive optical element (DOE) configured to change a cross-section of the focused light passing through the second lens unit to a predetermined shape.

The changed light passing through the DOE may be split into a plurality of lights, wherein the plurality of lights may include a first order light having a cross-section of the predetermined shape.

The optical system may include a prism positioned along a light path in a region where the light passes through the DOE.

The optical axis of the first order light may be bent by the prism such that the optical axis of the first order light is parallel to an optical axis of the focused light passing through the second lens unit.

An intensity of the first order light may be compensated for by the DOE.

The first order light may have a profile that is substantially symmetrical on both sides of a center line and is indented in a concave shape.

The optical system may include a mask along a light path of the light passing through the DOE, where the mask may be configured to block further order lights other than the first order light.

The optical path may include an optical fiber.

A cross-section of the optical fiber may be circular and a diameter of the cross-section of the optical fiber may be equal to or greater than 1 μm, and equal to or less than 200 μm.

The optical system may include a protective window along a light path of the light passing through the DOE.

A distance between the DOE and a focal point of the focused light passing through the second lens unit may be about 100 mm.

The light passing through the DOE may be radiated onto a sealing portion between a first substrate and a second substrate, and the sealing portion may be used to seal the first and second substrates.

The light passing through the DOE may be radiated in a shape of a spot beam.

According to another aspect of an embodiment of the present invention, a substrate sealing method is provided, the method including forming a sealing portion between a first substrate and a second substrate, passing light emitted from an end of an optical path through a first lens unit to change the emitted light to parallel light, passing the parallel light through a second lens unit to focus the parallel light to focused light, passing the focused light through a diffractive optical element (DOE) to change to a shaped light having a cross-section of a predetermined shape, and radiating the shaped light onto the sealing portion to seal the first substrate and the second substrate.

The passing the focused light through the DOE may divide the focused light to a plurality of lights, wherein the plurality of lights may include a first order light having a cross-section of the predetermined shape.

The substrate sealing method may pass the focused light that passes through the DOE through a prism, and may change the focused light, such that an optical axis of the first order light is parallel to an optical axis of the parallel light that passes through the second lens unit.

The substrate sealing method may compensate for an intensity of the focused light that passes through the DOE.

The substrate sealing method may block further order lights, other than the first order light.

The substrate sealing method may set a rotation axis of the DOE to a center of the first order light in a corner region of the sealing portion.

The first order light may include a beam profile wherein both sides of a center of the first order light are symmetrical to a center line of the first order light, and is indented in a concave shape.

The shaped light passing through the DOE may be radiated in a shape of a spot beam.

### BRIEF DESCRIPTION OF THE DRAWINGS

The above and other features and aspects of the present invention will become more apparent by describing in detail example embodiments thereof, with reference to the attached drawings in which:

FIG. 1 is a schematic cross-sectional view illustrating a method of sealing a sealing portion of an organic light-emitting display device using an optical system according to an embodiment of the present invention;

FIG. 2 is a top view of FIG. 1;

FIG. 3 illustrates a Gaussian beam profile as a first comparative example for comparison with a beam profile radiated by the optical system illustrated in FIG. 1;

FIG. 4 is a graph showing a temperature distribution according to a cross-section of frit when the Gaussian beam profile of FIG. 3 is radiated onto the frit of an organic light-emitting display device;

FIG. 5 illustrates a flat top beam profile as a second comparative example for comparison with the beam profile radiated by the optical system of FIG. 1;

FIG. 6 is a graph showing normalized temperature distribution according to a cross-section of the frit within an effective sealing width when the flat top beam profile of FIG. 5 and the Gaussian beam profile of FIG. 3 are radiated onto frit of the organic light-emitting display device;

FIG. 7 is a schematic view of a cross-sectional view of a laser beam according to an embodiment of the present invention;

FIG. 8 is a schematic view of an optical system according to another embodiment of the present invention;

FIG. 9 is a schematic plan view illustrating sealing in a straight line region of a sealing portion using the optical system illustrated in FIG. 8;

FIG. 10A is a schematic plan view illustrating sealing in a corner region of a sealing portion using the optical system of FIG. 8, according to an embodiment of the present invention;

FIG. 10B is a schematic plan view illustrating sealing in a corner region of a sealing portion using the optical system of FIG. 8, according to another embodiment of the present invention;

FIG. 10C is a schematic plan view illustrating sealing in a corner region of a sealing portion using the optical system of FIG. 8, according to another embodiment of the present invention;

FIG. 10D is a schematic plan view illustrating sealing in a corner region of a sealing portion using the optical system of FIG. 8, according to another embodiment of the present invention;

FIG. 11 is a schematic view of an optical system according to another embodiment of the present invention;

FIG. 12A is a schematic view illustrating a radiation direction of light when the intensity of first order light is not compensated;

FIG. 12B illustrates an intensity of first order light of FIG. 12A in a widthwise direction;

FIG. 13A is a schematic view illustrating a radiation direction of light when the intensity of first order light is not compensated for in a state in which a prism is used;

FIG. 13B illustrates an intensity of first order light of FIG. 13A in a widthwise direction;

FIG. 14A is a schematic view of a radiation direction of light when the intensity of first order light is compensated for;

FIG. 14B illustrates an intensity of first order light of FIG. 14A in a widthwise direction;

FIG. 15A is a schematic view of a radiation direction of light when the intensity of first order light is compensated for in a state in which a prism is used; and

FIG. 15B illustrates an intensity of first order light of FIG. 15A in a widthwise direction.

### DETAILED DESCRIPTION

In order to address the issues described in the background section, a substrate sealing method, whereby using frit as a sealant to improve adhesion between an OLED substrate and an encapsulation substrate, has been suggested.

By using a structure for sealing the organic light-emitting display device by applying frit onto a glass substrate, a space between the OLED substrate and the encapsulation substrate can be completely sealed such that the organic light-emitting display device can be protected more efficiently.

According to the method of sealing the substrate using frit, frit is applied to each sealing portion of the organic light-emitting display device, then each sealing portion of the organic light-emitting display device is irradiated by moving a laser beam so as to harden the frit and to seal the substrate.

The embodiments of the present invention will now be described in more details with reference to the accompanying drawings.

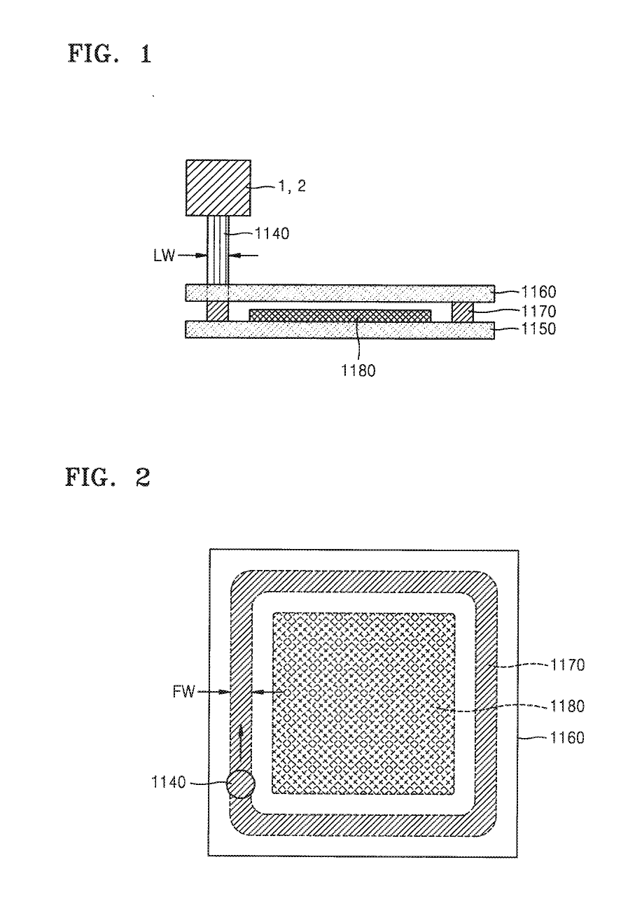

FIG. 1 is a schematic cross-sectional view illustrating a method of sealing a sealing portion 1170 of an organic light-emitting display device using optical systems 1 and 2 according to example embodiments of the present invention. FIG. 2 is a top view of FIG. 1.

Referring to FIGS. 1 and 2, an organic light-emitting portion 1180 and the sealing portion 1170 that surrounds the organic light-emitting portion 1180 are between a first substrate 1150 and a second substrate 1160. A laser beam 1140 is radiated onto the sealing portion 1170 by the optical systems 1 and 2.

The organic light-emitting portion 1180 is formed on the first substrate 1150. The first substrate 1150 may be a glass substrate.

The second substrate 1160 is an encapsulation substrate for encapsulating the organic light-emitting portion 1180 formed on the first substrate 1150. The second substrate 1160 may be a glass substrate through which a laser beam can pass, which will be described in detail below.

The organic light-emitting portion 1180 includes at least one organic light-emitting diode (OLED). The OLED includes at least one organic layer including a light-emitting layer interposed between a first electrode and a second electrode. In some embodiments, the first electrode and the second electrode may serve as an anode for hole injection and a cathode for electron injection, respectively.

The OLED may be classified as a passive-matrix organic light-emitting diode (PMOLED) or an active-matrix organic light-emitting diode (AMOLED), depending on whether or not driving of each OLED is controlled by a thin film transistor (TFT). According to an embodiment of the present invention, the OLED may either be a PMOLED or an AMOLED.

According to an embodiment of the present invention, the sealing portion 1170 is formed on the second substrate 1160 so as to surround the organic light-emitting portion 180.

The sealing portion 1170 may form a closed loop around the organic light-emitting portion 1180 so as to block the organic light-emitting portion 1180 from making contact with external moisture or oxygen.

Although each edge/corner of the sealing portion 1170 that forms the closed loop is shown as being curved with a predetermined curvature according to some embodiments of the present invention, aspects of the present invention are not limited thereto. That is, each edge/corner of the sealing portion 1170 may not necessarily have a curvature, and instead may be orthogonal.

In an embodiment where each edge/corner of the sealing portion 1170 has a predetermined curvature, the optical systems 1 and 2 may radiate a laser beam 1140 while successively scanning a sealing line including the edges/corners of the sealing portion 1170.

On the other hand, in an embodiment where each edge/corner of the sealing portion 1170 is orthogonal, after the optical systems 1 and 2 radiate the laser beam 1140 while scanning a first edge/corner of the sealing portion 1170 in a first direction, a stage that is located below the first substrate 1150 is rotated 90 degrees. When the stage is rotated, the first substrate 1150 and the second substrate 1160 are also rotated together with the stage. After the stage is rotated, when scanning is performed in the first direction as described above and the laser beam 1140 is radiated, the laser beam 1140 is radiated onto a second edge/corner of the sealing portion 1170. In this way, the sealing portion 1170 may be sealed by radiating the laser beam 1140 while rotating the stage.

According to an embodiment of the present invention, frit is used as the sealing portion 1170 so as to secure air tightness of the first substrate 1150 and the second substrate 1160 and to more effectively protect the organic light-emitting portion 1180. The frit may be formed to have a predetermined width, Frit Width (FW), according to various methods including screen printing, pen dispensing, and the like.

According to an embodiment of the present invention, the sealing portion 1170 is formed on the second substrate 1160 and the organic light-emitting portion 1180 is formed on the first substrate 1150 so as to substantially align the first substrate 1150 and the second substrate 1160; however, aspects of the present invention are not necessarily limited thereto. For example, the sealing portion 1170 may be formed on the first substrate 1150, where the organic light-emitting portion 1180 is also formed, and the first substrate 1150 may be aligned with the second substrate 1160 and combined therewith.

Also, although one light-emitting portion 1180 is shown in FIGS. 1 and 2, a plurality of organic light-emitting portions 1180 may be placed between the first substrate 1150 and the second substrate 1160, and a plurality of sealing portions 1170 may be formed to surround the plurality of organic light-emitting portions 1180.

According to an embodiment of the present invention, the optical systems 1 and 2 radiate the laser beam 1140 having a spot beam shape, with a beam profile according to various embodiments, onto the sealing portion 1170 formed between the first substrate 1150 and the second substrate 1160 along the sealing line. Detailed description thereof will be provided below.

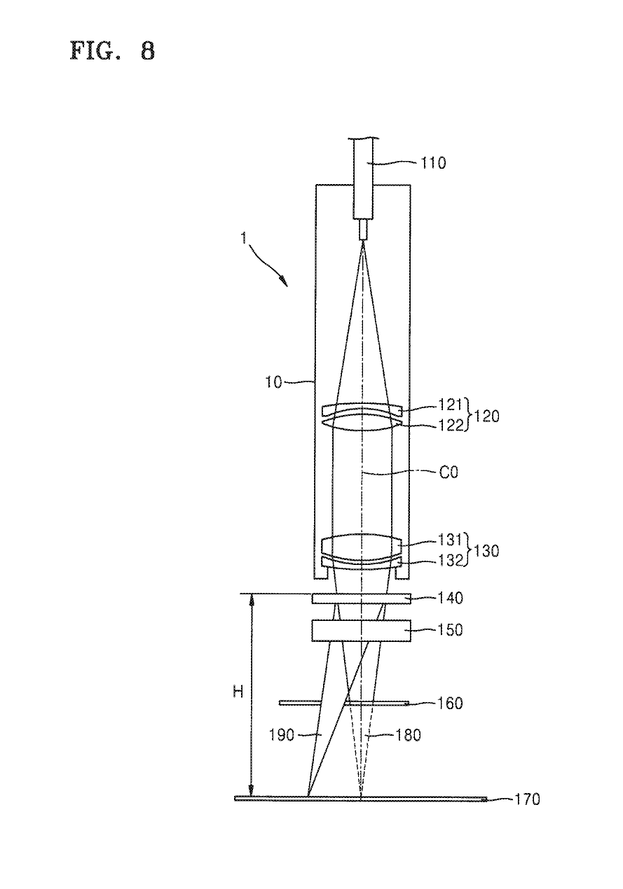

According to an embodiment of the present disclosure, the optical systems 1 and 2 may be connected to a laser oscillator that generates laser via an optical fiber (see 190 of FIG. 8). In some embodiments, the optical systems 1 and 2 may also include a beam homogenizer and a scanner.

In some embodiments, the laser oscillator may be a bundle type multi core source as a high-output laser source that is generally used for laser sealing.

Because core outputs in the bundle type multi core source may be slightly different from each other, the beam homogenizer may be used to overcome such non-uniformity.

In some embodiments, the scanner may include a reflector that reflects a laser beam radiated by the laser oscillator and radiates the laser beam onto the sealing portion 1170, a driving unit that drives the reflector, and a lens unit that focuses the reflected laser beam.

The laser beam 1140 that passes through the lens unit is radiated onto the sealing portion 1170 to have a spot beam shape with a beam profile according to the current embodiment. In this case, the lens unit may be inside the scanner or may be separately positioned below the scanner to face the sealing portion 1170.

In some embodiments, although not shown, when a width LW of the laser beam 1140 radiated by the optical systems 1 and 2 is greater than a width FW of the sealing portion 1170, a laser mask may be positioned between the optical systems 1 and 2 and the second substrate 1160 in order to adjust the width LW of the laser beam 1140 with respect to the width FW of the sealing portion 1170.

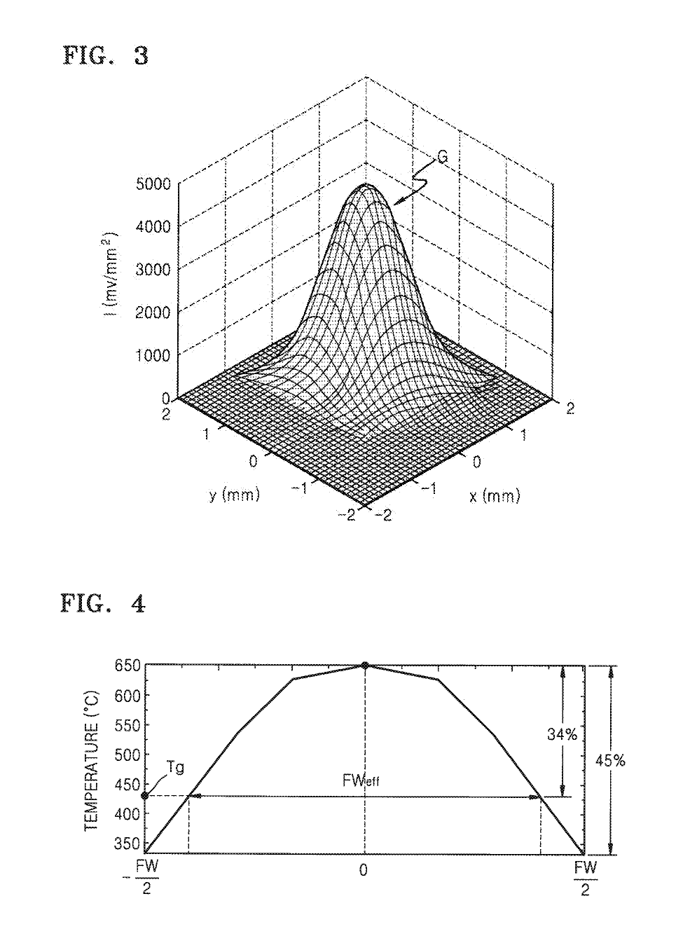

FIG. 3 illustrates a Gaussian beam profile as a first comparative example for comparison with a beam profile radiated by the optical system illustrated in FIG. 1.

FIG. 4 is a graph showing a temperature distribution according to a cross-section of the frit when the Gaussian beam profile of FIG. 3 is radiated onto the frit of an organic light-emitting display device.

Referring to FIG. 3, a laser beam profile G having the Gaussian distribution has a beam intensity I per unit area that increases closer to a beam center and has axial symmetry distribution.

The x-axis and the y-axis in the graph represent the width and a length of the beam profile G. Even if parts of peripheral portions adjacent to a central axis of the Gaussian beam profile G is cut using the laser mask, there is a difference of approximately 15% or more between the intensity at the center of the Gaussian beam profile G and the intensity of the peripheral portions cut by the laser mask.

In some embodiments, if the laser beam having the beam intensity difference between the beam center and the beam peripheral portion is radiated onto the frit that forms the sealing portion, as illustrated in FIG. 4, there is a temperature difference of approximately 45% or more between the center (a position in which the horizontal axis is 0) of the frit and the end (a position in which the horizontal axis is ±FW/2) of the frit, and there is a maximum temperature difference of approximately 34% between the center of the frit and the end of the frit within an effective sealing width FWeff that corresponds to approximately 80% of the whole sealing width FW.

According to an embodiment of the present disclosure, the laser output may be increased so as to maintain the temperature of the end of the frit at 430° C. or higher, which is a transition temperature Tg of the frit. In this case, the temperature of the center of the frit that is sealed by the center of the Gaussian beam profile G rises to approximately 650° C. or higher, and excessive heat is injected into the frit, thus causing the frit to be in an over-welded state.

Small voids that exist in the center of the frit expand larger than small voids that exist in the end of the frit when excessive energy is supplied. When the expanded small voids are rapidly cooled, stain like bubbles boil up, and may be left in the voids. The bubble stains are defects that cause the strength and adhesion force of the organic light-emitting display device to remarkably deteriorate.

Residual stress is determined by a thermal expansion coefficient and a cooled temperature difference. Because the center of the frit that has risen to a higher temperature is cooled slower than the end of the frit, tensile stress increases and cracks may occur when the center of the frit is shocked from the outside.

According to an embodiment of the present invention, a laser beam having a profile with a uniform beam intensity may be radiated onto the frit to solve the problem.

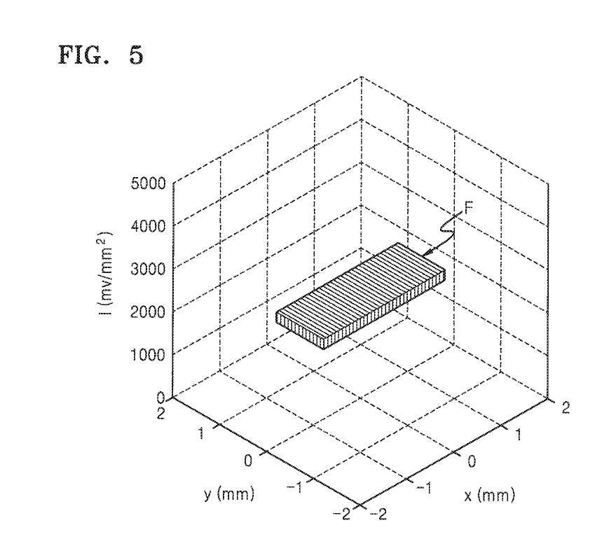

FIG. 5 illustrates a flat top beam profile as a second comparative example for comparison with the beam profile radiated by the optical system of FIG. 1.

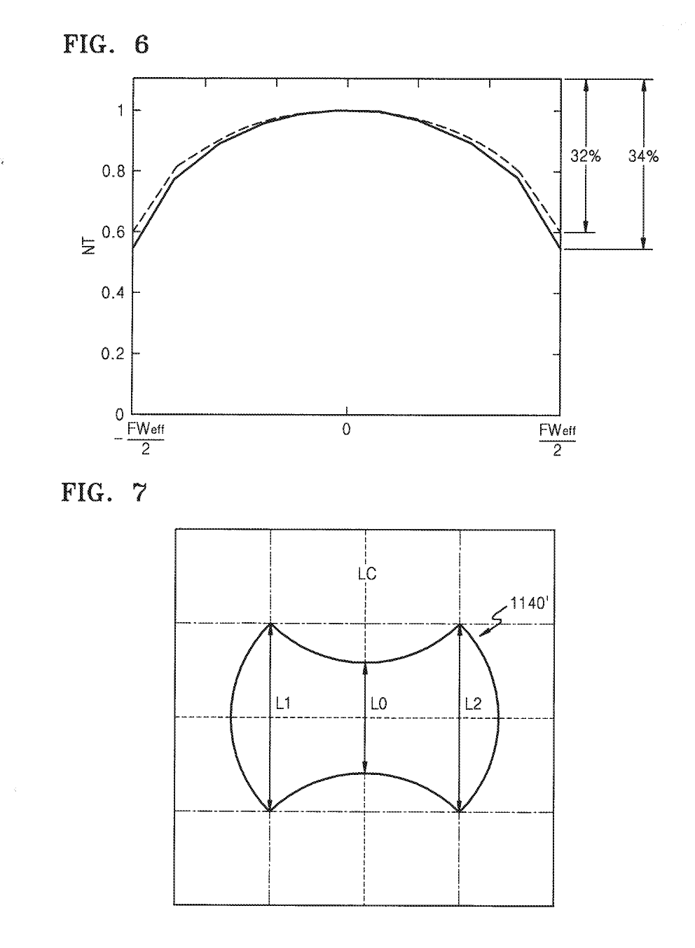

FIG. 6 is a graph showing normalized temperature distribution according to a cross-section of the frit within an effective sealing width when the flat top beam profile of FIG. 5 and the Gaussian beam profile of FIG. 3 are radiated onto the frit of the organic light-emitting display device.

Referring to FIG. 5, a laser beam profile F having the flat top distribution has a brick-shaped distribution in which a beam intensity I of a beam center, and a beam intensity I of a beam peripheral portion per unit area, are uniform.

The horizontal axis of FIG. 6 represents the position of frit within the effective sealing width FWeff, and the vertical axis NT of FIG. 6 represents a normalized temperature. Referring to FIGS. 5 and 6, even when the flat top laser beam F having a uniform beam intensity is radiated onto the frit, temperature uniformity of the cross-section of the frit decreases by approximately 2% (from approximately 34% to approximately 32%), and improvement of the temperature uniformity is negligible.

This is because heat is better dissipated outside, from the end of the frit than from the center of the frit. That is, making the intensity of the laser beam radiated onto the frit uniform may not necessarily be a solution for solving the above-described problems, but the solution may be to make temperature distribution according to the cross-section of the frit uniform after the laser beam is radiated onto frit. Thus, larger energy than the energy applied to the center of the frit may be applied additionally, to the end of the frit.

Hereinafter, a laser beam profile which may improve the temperature distribution uniformity along the cross-section of the frit when a substrate is sealed using the optical systems 1 and 2 of FIG. 1 will be described with reference to FIG. 7.

FIG. 7 is a schematic view of a cross-section of a laser beam 1140′ according to an embodiment of the present invention.

Referring to FIG. 7, the laser beam 1140′ has an overall uniform beam intensity and has a beam profile in which both sides of a center of the laser beam 1140′ are symmetrical or substantially symmetrical to a laser beam center line LC and are indented in a concave shape. Length L0 of a center line of the laser beam 1140′ is smaller than lengths L1 and L2, parallel to the beam center line LC, of the peripheral portions of the laser beam 1140′.

Thus, like in the above-described embodiment, a heat flux (e.g., heat flux that has an integral value of the intensity of a laser beam that is scanned along a center line of a sealing line FL and is radiated) over time in the end of the sealing portion 1170, is larger than a heat flux in the center of the sealing portion 1170.

Thus, when the laser beam 1140′ having the beam profile, as described above, is radiated onto the sealing portion 1170 of the organic light-emitting display device, an energy larger than the energy applied to the center of the sealing portion 1170 is supplied to the end of the sealing portion 1170. Thus, the temperature uniformity of the cross-section of the frit may be improved.

Hereinafter, the optical systems 1 and 2 that may form other beam profiles having various shapes rather than the beam profile in which both sides of the center of the laser beam are indented in a concave shape, will be described.

FIG. 8 is a schematic view of the optical system 1 of FIG. 1.

Referring to FIG. 8, the optical system 1 according to an embodiment of the present invention may include an optical path 110, a first lens unit 120, a second lens unit 130, a diffractive optical element (DOE) 140, a protective window 150, and a mask 160.

According to an embodiment of the present invention, the laser beam may be emitted from an end of the optical path 110. The optical path 110 may include, for example, an optical fiber. A cross-section of the optical fiber may be circular, and a diameter of the cross-section of the optical fiber may be equal to or greater than 1 μm, and equal to or less than 200 μm. The laser beam emitted from the end of the optical path 110 may be in multi-modes. As the diameter of the cross-section of the optical fiber increases, characteristics of multi-modes are further shown so that a laser beam having a desired shape cannot be easily obtained through the DOE 140. Thus, the diameter of the optical fiber is limited to being equal to or greater than 1 μm and equal to or less than 200 μm so that characteristics similar to that of a single mode are shown, and a laser beam having a desired shape can be obtained through the DOE 140. If the diameter of the optical fiber decreases, the size of an image formed on a focus may concurrently (e.g., simultaneously) increase. Thus, a magnification of the second lens unit 130 may be adjusted so as to obtain an image having a desired size.

According to an embodiment of the present disclosure, the first lens unit 120 changes light emitted from the end of the optical path 110 to a parallel light. The first lens unit 120 may include a plurality of lenses. The first lens unit 120 may be configured using a combination of a concave lens 121 and a convex lens 122.

According to an embodiment of the present disclosure, the second lens unit 130 allows the parallel light that passes through the first lens unit 120 to be focused on a target 170. The second lens unit 130 may include a plurality of lenses. The second lens unit 130 may be configured using a combination of a convex lens 131 and a concave lens 132.

According to an embodiment of the present disclosure, the DOE 140 may change light that passes through the second lens unit 130 to light having a cross-section of a predetermined shape. The shape of the cross-section with the predetermined shape may be a cross-section as illustrated in FIG. 7.

The DOE 140 is a structure in which a micro element is formed on the surface of a glass substrate by etching or e-beam. When a beam that passes through the second lens unit 130 is focused on the DOE 140 to a predetermined size, a very large number (e.g., an infinite number) of micro optical elements on the surface of the DOE 140 diffracts the beam to configure a desired shape on the target 170.

As the light passes through the second lens unit 130, and passes through the DOE 140, the light is split into a plurality of lights. The plurality of lights are divided into zero order light 180, first order light 190, and further order lights (e.g., second order, third order, etc.) due to the diffraction phenomenon.

The cross-section of the zero order light 180 may have a shape of a small dot. An optical axis of the zero order light 180 is substantially the same as that of the light immediately before passing through the DOE 140, i.e., light that passes through the second lens unit 130. The zero order light 180 may not be a desired image and thus may be removed by using any suitable method known to those skilled the art.

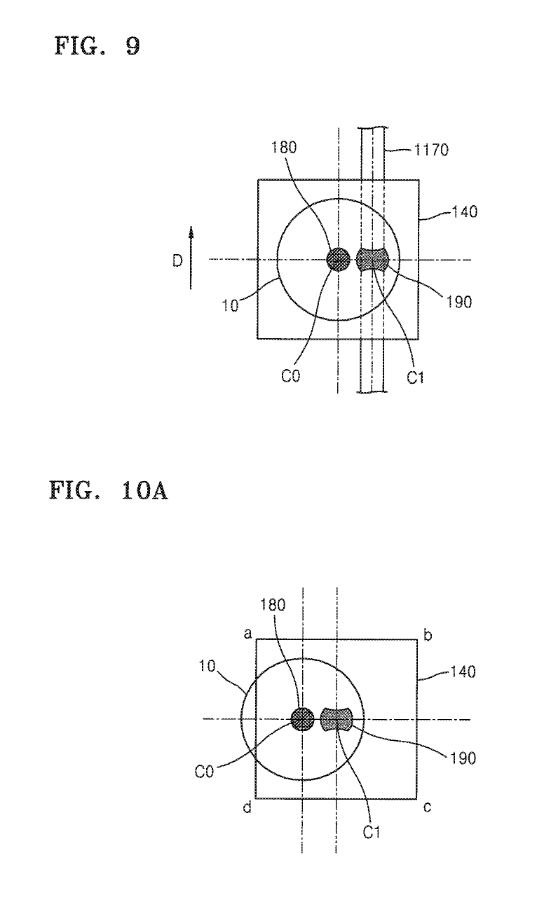

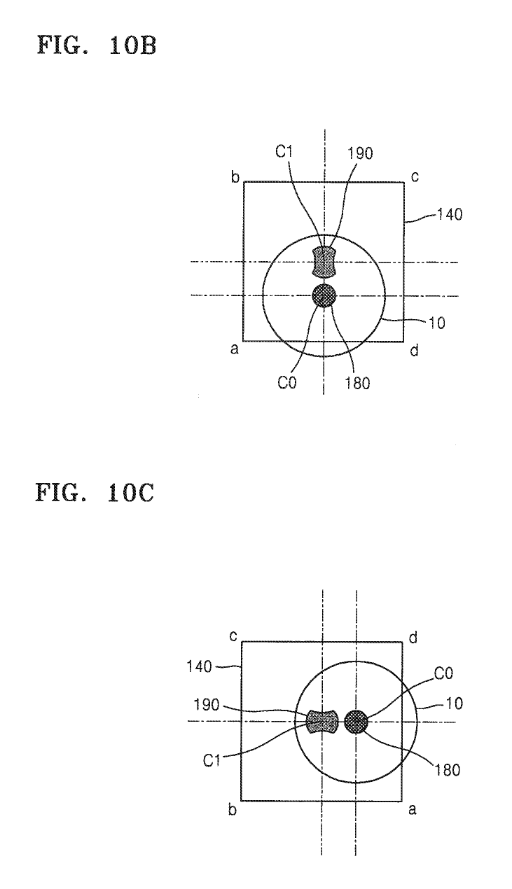

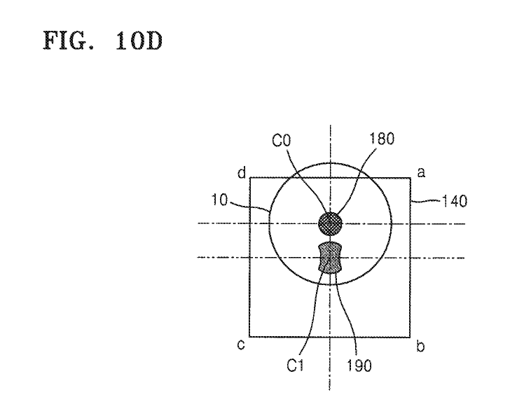

In some embodiments, the first order light 190 and further order lights may be formed with different predetermined angles. The first order light 190 may be bent (e.g., refracted) with respect to the zero order light 180 at an angle of less than 5 degrees. In some embodiments, the cross-section of the first order light 190 may have a predetermined shape. The cross-section with the predetermined shape may have the shape of the cross-section illustrated in FIG. 7. That is, the first order light 190 may be the laser beam 1140′ illustrated in FIG. 7. Thus, the first order light 190 may have a beam profile in which both sides of a center of the first order light 190 are symmetrical or substantially symmetrical to a center line LC of the first order light 190 and are indented in a concave shape. As such, light having a cross-section with a desired shape may be radiated onto the sealing portion 1170 of the organic light-emitting display device in order to improve the strength and adhesion force of the organic light-emitting display device. Substrate sealing using the first order light 190 will be described below in detail with reference to FIGS. 9 and 10A-10D.

Because the further order lights may not be desired images like the zero order light 180, they may also be removed using any suitable method known to those skilled in the art.

In some embodiments, a working distance of the DOE 140 may be fixed. That is, a distance H between the DOE 140 and a position in which light that passes through the second lens unit 130 is focused, may be fixed. The DOE 140 may be configured to shape a beam at a predetermined working distance of, for example, 100 mm. Thus, when the DOE 140 has a predetermined working distance, the first lens unit 120 or the second lens unit 130 may be moved in a vertical direction in order to enlarge or reduce the size of the final image.

In some embodiments, the protective window 150 may be arranged along a light path in which the light passes through the DOE 140. Since micro elements are formed on a surface of the DOE 140, if foreign substances on the surface of the sealing portion 1170, or foreign substances on the first substrate 1150 are attached to the surface of the DOE 140, it may be difficult to clean the DOE 140. Thus, the protective window 150 may be arranged below the DOE 140 so that foreign substances may be prevented from being attached to the DOE 140, and improve the life span of the DOE.

According to an embodiment of the present invention, the mask 160 may be disposed along the light path in which light passes through the DOE 140. That is, the mask 160 may be arranged below the protective window 150. The further order lights (e.g., lights other than the first order light) 190 may not be desired images. Thus, the first order light 190 that generates a desired image may be configured to pass through the DOE 140 via the mask 160, and the further order lights may be blocked via the mask 160. The mask 160 may be moved along the path of the first order light 190.

FIG. 9 is a schematic plan view illustrating sealing in a straight line region of the sealing portion 1170 using the optical system 1 of FIG. 9.

Referring to FIG. 9, a center C1 of the first order light 190 may be positioned at the sealing portion 1170 so that the optical system 1 may seal a substrate while moving a lens barrel 10 in a substantially straight line direction D.

Because the first order light 190 may be bent with respect to the zero order light 180 at a predetermined angle, a central axis C0 of the lens barrel 10 and the center C1 of the first order light 190 are spaced apart from each other (e.g., spaced apart by a predetermined distance). In FIG. 9, the central axis C0 of the lens barrel 10 may be rotated around an outer side or an inner side of a track of the sealing portion 1170 depending on a design of the DOE 140.

FIGS. 10A through 10D are plan views illustrating sealing in a corner region of the sealing portion 1170 using the optical system 1 of FIG. 9.

Since the substrate is sealed as the first order light 190 moves along the sealing portion 1170, the first order light 190 in the corner region of the sealing portion 1170 is rotated based on the center C1 of the first order light 190.

The first order light 190 is changed from the state of FIG. 10A to states of FIGS. 10B, 10C, and 10D by rotating in a counterclockwise direction, 90 degrees, 180 degrees, and 270 degrees, respectively. As such, the first order light 190 is returned to the state of FIG. 10A when rotated 360 degrees.

Referring to FIG. 10B, from the state shown in FIG. 10A, the DOE 140 is rotated 90 degrees counterclockwise and concurrently (e.g., simultaneously), a relative position of the DOE 140 with respect to the lens barrel 10 is moved, and the first order light 190 is rotated 90 degrees counterclockwise. Thus, the first order light 190 is rotated 90 degrees counterclockwise from the state shown in FIG. 10A.

Referring to FIG. 10C, from the state shown in FIG. 10B, the DOE 140 is rotated 90 degrees counterclockwise and concurrently (e.g., simultaneously), a relative position of the DOE 140 with respect to the lens barrel 10 is moved, and the first order light 190 is rotated 90 degrees counterclockwise. Thus, the first order light 190 is rotated 180 degrees counterclockwise from the state shown in FIG. 10A.

Referring to FIG. 10D, from the state shown in FIG. 10C, the DOE 140 is rotated 90 degrees counterclockwise and concurrently (e.g., simultaneously), a relative position of the DOE 140 with respect to the lens barrel 10 is moved, and the first order light 190 is rotated 90 degrees counterclockwise. Thus, the first order light 190 is rotated 270 degrees counterclockwise from the state shown in FIG. 10A.

Referring to FIG. 10A, from the state shown in FIG. 10D, the DOE 140 is rotated 90 degrees counterclockwise and concurrently (e.g., simultaneously), a relative position of the DOE 140 with respect to the lens barrel 10 is moved, and the first order light 190 is rotated 90 degrees counterclockwise. Thus, the first order light 190 is rotated 360 degrees counterclockwise from the state shown in FIG. 10A.

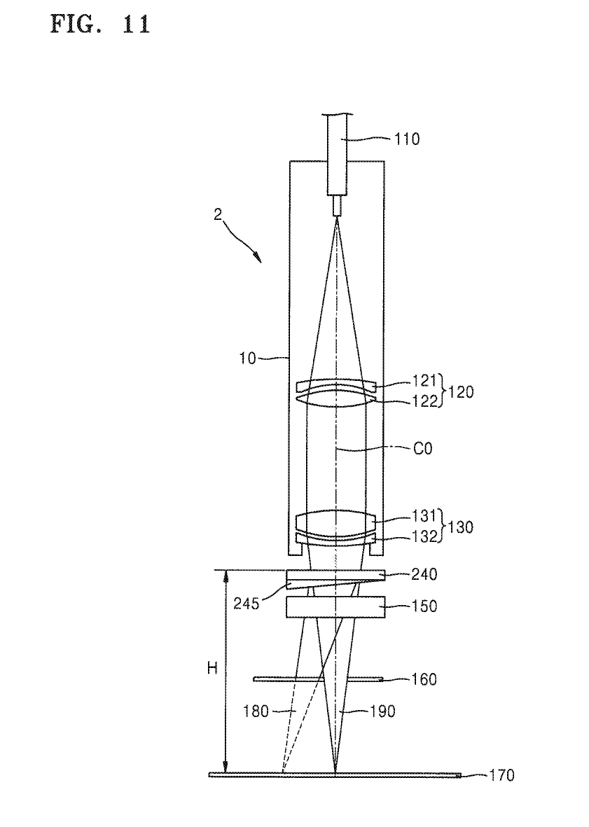

A rotation axis of the DOE 140 in the corner region of the sealing portion 1170 may be set to the center C1 of the first order light 190 by rotation and movement of the DOE 140. In some embodiments, it may be desired to rotate and move the DOE 140 to move the DOE 140 relative to the lens barrel 10. Thus, the area of the DOE 140 in some embodiments may be increased relative to the area of a DOE 240 of an optical system 2, as illustrated in FIG. 11, according to another embodiment of the present invention.

Although the above descriptions are based on rotation and movement of the DOE 140, a similar operation may be performed by rotation and movement of the lens barrel 10.

FIG. 11 is a schematic view of the optical system 2 according to another embodiment of the present invention.

Hereinafter, aspects of the embodiment will be described based on differences between FIGS. 8 and 11. Like reference numerals are used for like elements having the same or substantially similar functions from those of FIGS. 8 and 11.

Referring to FIG. 11, the optical system 1 according to another embodiment of the present invention may include an optical path 110, a first lens unit 120, a second lens unit 130, a DOE 240, a prism 245, a protective window 150, and a mask 160.

As light that passes through the second lens unit 230 passes through the DOE 240, the light is split into a plurality of lights. The plurality of lights are divided into zero order light 180, first order light 190, and further order (e.g., second order, third order, etc.) lights due to the diffraction phenomenon.

An optical axis of the zero order light 180 before passing through the prism 245 is substantially the same as that of light immediately before passing through the DOE 240, (the light that passes through the second lens unit 130).

In some embodiments, the first order light 190 and further order lights are formed with different predetermined angles. The first order light 190 may be bent or twisted with respect to the zero order light 180 at an angle of less than or equal to 5 degrees. The first order light 190 may have a cross-section with a predetermined shape. The cross-section with the predetermined shape may be the cross-section illustrated in FIG. 7. That is, the first order light 190 may be the laser beam 1140′ illustrated in FIG. 7. Thus, the first order light 190 may have a beam profile in which both sides of a center of the first order light 190 are symmetrical to a center line LC of the first order light 190 and are indented in a concave shape.

In some embodiments, the prism 245 may be positioned along a light path in which light passes through the DOE 240. The prism 245 may be wedge-shaped, but is not limited thereto. As the prism 245 is coupled to the DOE 240 or is arranged below the DOE 240, the optical axis of the first order light 190 and optical axes of the further order lights may be bent or twisted. As such, the optical axis of the first order light 190 may be parallel to the optical axis of light that passes through the second lens unit 130 due to the prism 245. In more detail, the optical axis of the first order light 190 is bent or twisted due to the prism 245 so that the optical axis of the first order light 190 may be substantially the same as the central axis C0 of the lens barrel 10. Since the first order light 190 has a cross-section with a desired shape and the optical axis of the first order light 190 may be substantially the same as the central axis C0 of the lens barrel 10, the central axis C0 of the lens barrel 10 may be positioned at the sealing portion 1170 so as to seal a substrate. Thus, sealing may be easily performed along a track of the sealing portion 1170.

When sealing is performed in the corner region of the sealing portion 1170 using the optical system 2 of FIG. 11, the cross-section of the first order light 190 may be rotated by rotation of the DOE 240. In some embodiments, the optical axis of the first order light 190 may be substantially the same as the central axis C0 of the lens barrel 10. Thus, the DOE 240 may be rotated based on the central axis C0 of the lens barrel 10 without resetting the rotation axis of the DOE 240 in the corner region of the sealing portion 1170 so that sealing in the corner region may be performed.

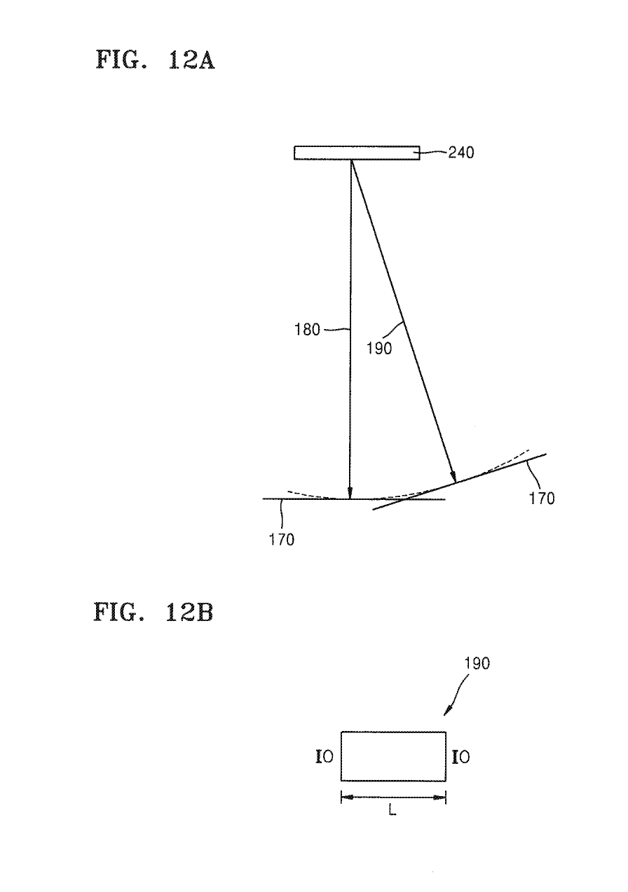

According to an embodiment of the present disclosure, FIG. 12A illustrates a light radiation direction when the intensity of the first order light 190 is not compensated for, and FIG. 12B illustrates an intensity of the first order light 190 of FIG. 12A in a widthwise direction L.

Referring to FIG. 12A, as a laser beam passes through the DOE 240, the laser beam is split into a plurality of lights. The plurality of lights are divided into zero order light 180, first order light 190, and further order (e.g., second order, third order, etc.) lights due to the diffraction phenomenon.

An optical axis of the zero order light 180 is substantially the same as that of the light immediately before passing through the DOE 140 (i.e., the light that passes through the second lens unit 130). The first order light 190 and further order lights are formed with different predetermined angles. The first order light 190 may be bent or twisted with respect to the zero order light 180 at an angle of less than or equal to approximately 5 degrees.

Referring to FIG. 12B, the intensity of the first order light 190 that is focused on the target 170 in the widthwise direction L is a substantially uniform, I0.

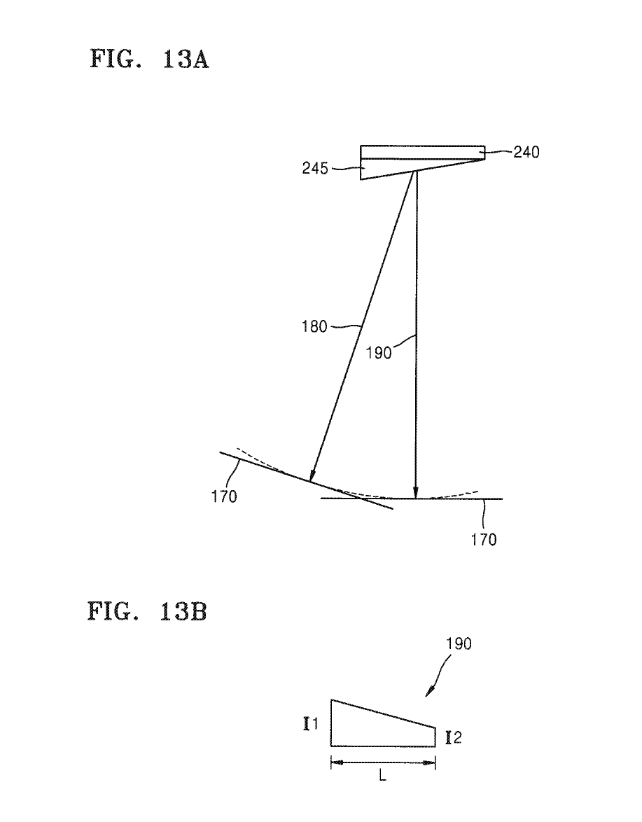

According to an embodiment of the present disclosure, FIG. 13A is a schematic view illustrating a light radiation direction when the intensity of the first order light 190 is not compensated for in a state in which the prism 245 is arranged, and FIG. 13B illustrates an intensity of the first order light 190 of FIG. 13A in the widthwise direction L.

Referring to FIG. 13A, an optical axis of the first order light 190 is substantially the same as that of light immediately before passing through the DOE 240 (the light that passes through the second lens unit 130 due to the prism 245). The zero order light 180 and the further order lights are formed with predetermined angles.

Referring to FIG. 13B, the intensity of the first order light 190 that is focused on the target 170, in the widthwise direction L is inclined. That is, the intensity of the first order light 190 is changed from I1 to I2 in the widthwise direction L. The optical axis of the first order light 190 is bent or twisted by the prism 245 so that the intensity of the first order light 190 in the widthwise direction L may also be inclined.

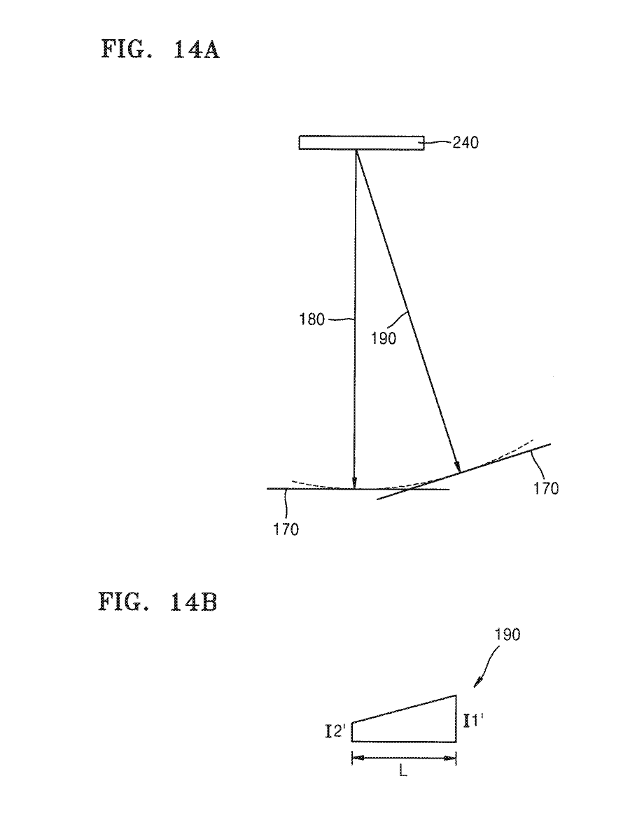

According to an embodiment of the present disclosure, FIG. 14A is a schematic view of a light radiation direction when the intensity of the first order light 190 is compensated for, and FIG. 14B illustrates an intensity of the first order light 190 of FIG. 14A in the widthwise direction L.

Referring to FIG. 14A, an optical axis of the zero order light 180 is substantially the same as that of light immediately before passing through the DOE 240 (the light that passes through the second lens unit 130). The first order light 190 and the further order lights are formed with different predetermined angles. The first order light 190 may be bent or twisted with respect to the zero order light 180 at an angle of less than or equal to 5 degrees.

Referring to FIG. 14B, the intensity of the first order light 190 is compensated for so that the intensity of the first order light 190 that is focused on the target 170, in the widthwise direction L may be inclined. That is, the intensity of the first order light 190 is changed from I1′ to I2′ in the widthwise direction L. The intensity of the first order light 190 may be compensated for by the DOE 240. The intensity of the first order light 190 may be adjusted by a controller of a laser light source.

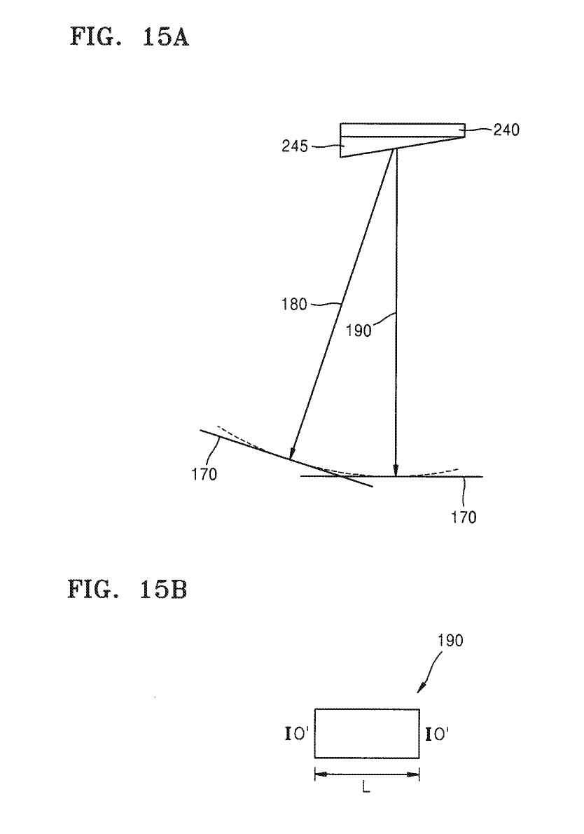

According to an embodiment of the present disclosure, FIG. 15A is a schematic view of a light radiation direction when the intensity of the first order light 190 is compensated for in a state in which the prism 245 is arranged, and FIG. 15B illustrates an intensity of the first order light 190 of FIG. 15A in the widthwise direction L.

Referring to FIG. 15A, an optical axis of the first order light 190 is substantially the same as that of light immediately before passing through the DOE 240 (the light that passes through the second lens unit 130). The zero order light 180 and further order lights are formed with predetermined angles.

Referring to FIG. 15B, the intensity of the first order light 190 that is focused on the target 170, in the widthwise direction L is a substantially uniform I0′. Since the intensity of the first order light 190 in the widthwise direction L has been already inclined before the prism 245 (see FIG. 14B), the optical axis of the first order light 190 is bent or twisted by the prism 245 so that the intensity of the first order light 190 in the widthwise direction L may be substantially uniform. The inclination of the intensity of the first order light 190 in the widthwise direction L before the prism 245 is arrange may be adjusted so that the intensity of the first order light 190 in the widthwise direction L after the prism 245 may be substantially uniform.

As such, light having a cross-section with a desired shape and a substantially uniform intensity in a widthwise direction is radiated onto the sealing portion 1170 of the organic light-emitting display device so that the strength and adhesion force of the organic light-emitting display device can be improved.

As described above, when light that passes through the optical system according to the one or more embodiments of the present invention is radiated onto a sealing portion of a display device, the strength and adhesion force of the display device can be improved.

While the embodiments of the present invention has been particularly shown and described with reference to various embodiments thereof, it will be understood by those of ordinary skill in the art that various changes in form and details may be made therein without departing from the spirit and scope of the embodiments of the present invention as defined by the following claims, and equivalents thereof.

What is claimed is:

1. An optical system comprising:
an optical path;
a first lens unit configured to change light emitted from an end of the optical path to parallel light;
a second lens unit configured to focus the parallel light; and
a diffractive optical element (DOE) configured to change a cross-section of the focused light passing through the second lens unit to a predetermined shape.

2. The optical system of claim 1, wherein the changed light passing through the DOE is split into a plurality of lights, the plurality of lights comprising a first order light having a cross-section of the predetermined shape.

3. The optical system of claim 2, further comprising a prism positioned along a light path in a region where the light passes through the DOE.

4. The optical system of claim 3, wherein an optical axis of the first order light is bent by the prism, such that the optical axis of the first order light is parallel to an optical axis of the focused light passing through the second lens unit.

5. The optical system of claim 3, wherein an intensity of the first order light is compensated for by the DOE.

6. The optical system of claim 2, wherein the first order light has:
a profile that is substantially symmetrical on both sides of a center line; and
indented in a concave shape.

7. The optical system of claim 2, further comprising a mask along a light path of the light passing through the DOE, the mask being configured to block further order lights other than the first order light.

8. The optical system of claim 1, wherein the optical path comprises an optical fiber.

9. The optical system of claim 8, wherein a cross-section of the optical fiber is circular and a diameter of the cross-section of the optical fiber is equal to or greater than 1 μm, and equal to or less than 200 μm.

10. The optical system of claim 1, further comprising a protective window along a light path of the light passing through the DOE.

11. The optical system of claim 1, wherein a distance between the DOE and a focal point of the focused light passing through the second lens unit is about 100 mm.

12. The optical system of claim 1, wherein the light passing through the DOE is radiated onto a sealing portion between a first substrate and a second substrate, the sealing portion being used to seal the first and second substrates.

13. The optical system of claim 1, wherein the light passing through the DOE is radiated in a shape of a spot beam.

14. A substrate sealing method comprising:
forming a sealing portion between a first substrate and a second substrate;
passing light emitted from an end of an optical path through a first lens unit to change the emitted light to parallel light;
passing the parallel light through a second lens unit to focus the parallel light to focused light;
passing the focused light through a diffractive optical element (DOE) to change to a shaped light having a cross-section of a predetermined shape; and
radiating the shaped light onto the sealing portion to seal the first substrate and the second substrate.

15. The substrate sealing method of claim 14, wherein the passing the focused light through the DOE comprises dividing the focused light to a plurality of lights, the plurality of lights comprising a first order light having a cross-section of the predetermined shape.

16. The substrate sealing method of claim 15, further comprising:
passing the focused light that passes through the DOE through a prism; and
changing the focused light such that an optical axis of the first order light is parallel to an optical axis of the parallel light that passes through the second lens unit.

17. The substrate sealing method of claim 16, further comprising compensating for an intensity of the focused light that passes through the DOE.

18. The substrate sealing method of claim 15, further comprising blocking further order lights, other than the first order light.

19. The substrate sealing method of claim 15, further comprising setting a rotation axis of the DOE to a center of the first order light in a corner region of the sealing portion.

20. The substrate sealing method of claim 15, wherein the first order light comprises:
a beam profile wherein both sides of a center of the first order light are symmetrical to a center line of the first order light; and
indented in a concave shape.

21. The substrate sealing method of claim 14, wherein the optical path comprises an optical fiber.

22. The substrate sealing method of claim 21, wherein a cross-section of the optical fiber is circular and a diameter of the cross-section of the optical fiber is equal to or greater than 1 μm and equal to or less than 200 μm.

23. The substrate sealing method of claim 14, wherein a distance between the DOE and a focal point of the focused light passing through the second lens unit is 100 mm.

24. The substrate sealing method of claim 14, wherein shaped light passing through the DOE is radiated in a shape of a spot beam.
